(19) United States
(12) Patent Application Publication
(10) Pub. No.: US 2025/0038722 A1
(43) Pub. Date: Jan. 30, 2025

(54) SYSTEMS AND METHODS FOR TUNABLE PARAMETRIC AMPLIFICATION

(71) Applicant: D-WAVE SYSTEMS INC., Burnaby (CA)

(72) Inventors: Loren J. Swenson, San Jose, CA (US); Jed D. Whittaker, Vancouver (CA); George E.G. Sterling, Vancouver (CA)

(21) Appl. No.: 18/716,679

(22) PCT Filed: Dec. 6, 2022
(86) PCT No.: PCT/US2022/081029

§ 371 Date: Jun. 5, 2024

Related U.S. Application Data
(60) Provisional application No. 63/265,131, filed on Dec. 8, 2021.

(51) Int. Cl. H03F 7/00; H03F 19/00

(52) U.S. Cl. CPC H03F 7/00; H03F 19/00

(57) ABSTRACT

In an implementation, a tunable traveling wave parametric amplifier (TWPA) includes a T-stage that includes a first DC-SQUID and a first interface inductively communicatively coupled to the first DC SQUID operable to apply a first bias to the first DC SQUID. The T-stage also includes a second DC-SQUID electrically communicatively coupled to the first DC-SQUID in series via a center node, and a second interface inductively communicatively coupled to the second DC-SQUID operable to apply a second bias to the second DC-SQUID. The TWPA also includes a shunting resonator communicatively coupled to the center node via a coupling capacitance. The shunting resonator includes a third DC-SQUID, and a third interface inductively communicatively coupled to the third DC SQUID operable to apply a third bias to the third DC SQUID. The first, second, and third biases are adjustable to improve a bandwidth of the tunable TWPA.

### CROSS-REFERENCE TO RELATED APPLICATION

This patent application claims priority of U.S. Patent Application No. 63/265,131, filed on Dec. 8, 2021, the entire disclosure of which is hereby incorporated by reference herein for all purposes.

### FIELD

This disclosure generally relates to systems and methods for tunable parametric amplification, and, in particular, to circuits for a tunable parametric amplifier, for example, a parametric amplifier suitable for use in a readout circuit of a quantum computer.

### BACKGROUND

### Quantum Computing

Quantum computers may perform two general types of quantum computation. The first, quantum annealing and/or adiabatic quantum computation, generally relies on the physical evolution of a quantum system. Gate model quantum computation relies on the use of quantum gate operations to perform computations with data. Gate model quantum computing may also be referred to as “circuit model quantum computing” hereinafter. Surface code refers to a particular implementation of error-corrected gate or circuit quantum computation (QC), in which logical qubits are encoded into portions or patches of a square lattice of physical qubits using a two-dimensional low density parity check scheme.

### Superconducting Processor

A computer processor may take the form of an analog processor, for example, a superconducting quantum processor. A superconducting quantum processor may include two or more superconducting qubits. Further detail and embodiments of exemplary quantum processors that may be used in conjunction with the present systems, methods, and apparatus are described in U.S. Pat. Nos. 7,533,068, 8,195,596, 8,190,548, and International PCT Patent Application Serial No. PCT/US2009/037984.

A superconducting processor may be a processor that is not intended for quantum computing, and operates, for example, by principles that govern the operation of classical computer processors.

A computing system may in general include a quantum processor and/or a classical processor. A computing system may be a hybrid system that includes a quantum processor and a classical processor. In some implementations, at least one of the quantum processor and the classical processor is a superconducting processor.

### Superconducting Qubits

Superconducting qubits may be formed in a superconducting integrated circuit from a superconductive material (e.g., aluminum and/or niobium). A material is a superconductive material if there is a temperature below which the material can superconduct.

Superconducting qubits may be charge, flux, or phase qubits, for example. Charge qubits can store and manipulate information in charge states of the qubit. Flux qubits can store and manipulate information in a variable related to a magnetic flux through a portion of the qubit. Phase qubits can store and manipulate information in a variable related to a difference in a superconducting phase between two regions of the qubit. Hybrid devices can use two or more of charge, flux, and phase degrees of freedom.

Superconducting qubits commonly include at least one Josephson junction. A Josephson junction is a small interruption in an otherwise continuous superconducting current path and is typically realized by a thin insulating barrier sandwiched between two superconducting electrodes. A Josephson junction can be formed as a three-layer or “trilayer” structure. Superconducting qubits are further described in, for example, U.S. Pat. Nos. 7,876,248, 8,035,540, and 8,098,179.

Some implementations of superconducting flux qubits include a superconducting loop that is interrupted by at least one Josephson junction. Some implementations include multiple superconducting loops connected in series and/or in parallel with one another. Some implementations include multiple Josephson junctions connected either in series or in parallel with one another.

### Parametric Amplification

Parametric amplification is an amplification of a signal using a parametric nonlinearity and a pump wave. Some parametric amplifiers are electronic parametric amplifiers, and others are optical parametric amplifiers.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

In quantum computing generally, microwave signals are often used for control and readout of a quantum processor. In some cases, it may be beneficial to amplify and/or filter these signals. Travelling wave parametric amplifiers (TWPAs) are a type of device that may be used to perform this amplification, as well as behave as an active microwave switch. Parametric amplifiers can beneficially be used in quantum computing systems to increase the signal from components, for example, to increase the signal-to-noise ratio of resonator-coupled qubit measurements. For example, qubit measurements may be performed by coupling the qubit with a resonator, and then sending a signal at a particular frequency from the resonator through a transmission line. Amplification of a signal from a qubit may decrease the data acquisition time and increase the likelihood of an accurate readout. Fabrication variation in forming readout resonators may impact the device frequency, and it can be beneficial to have the amplified frequency of a TWPA be adjustable to accommodate this variation. The TWPA may be operated as a microwave switch by adjusting the transmission line impedance between almost all of the power being transmitted to almost none of the power being transmitted.

A TWPA can be defined by a pump tone frequency, a stop-band, and a gain. The pump tone frequency describes the frequency that is amplified by the TWPA. Gain is a measure of the amount of amplification that a TWPA can provide to a given signal, and in some cases may be dependent on the frequency of the signal. Reducing the dependence of gain on frequency due to impedance mismatch between the TWPA and microwave feedlines, also referred to as the “ripple”, can beneficially increase the amplification of the signals and cause that amplification to be more uniform. A stop-band provides a band of frequencies that are not allowed to pass through the TWPA. For example, in the case of a qubit readout, these may be frequencies that are associated with noise in the system. For example, a stop-band may be used to suppress gain for frequencies close to the pump tone frequency. In some implementations, the width of the stop-band, which defines the resolution of frequencies that can be suppressed, is set by the coupling between the transmission line and the resonators, as well as by frequency variations between resonators. A narrower stop-band can provide greater resolution, and therefore a greater available bandwidth. Further, by providing a stop-band having an adjustable width, a selection of frequencies that are not allowed to pass can be tuned for a particular implementation. A stop-band having an adjustable position can allow for a single device to omit different frequencies, allowing for frequencies near different pump tone frequencies to be suppressed.

Providing a TWPA having increased gain, decreased ripple, a decreased stop-band width with an adjustable position, and/or an adjustable pump tone frequency can result in a device having increased performance in amplification and filtering of signals such as qubit readout signals and other microwave signals in a processor. This can increase readout fidelity, thereby providing more accurate results from a quantum computer.

A tunable traveling wave parametric amplifier (TWPA) may be summarized as comprising a first T stage, the first T-stage comprising a first DC-SQUID, a first interface inductively communicatively coupled to the first DC SQUID, the first interface operable to apply a first bias to the first DC SQUID, a second DC-SQUID electrically communicatively coupled to the first DC-SQUID in series via a first center node, a second interface inductively communicatively coupled to the second DC-SQUID, the second interface operable to apply a second bias to the second DC-SQUID, a first resonator communicatively coupled to the first center node via a first coupling capacitance, the first resonator shunted to a ground, the first resonator comprising a first resonator capacitance, a first resonator inductance, and a third DC-SQUID, and a third interface inductively communicatively coupled to the third DC SQUID, the third interface operable to apply a third bias to the third DC SQUID, wherein the first bias and the second bias are adjustable to reduce a ripple in a gain versus frequency response of the tunable TWPA, and the third bias is adjustable to tune a position and a width of a stop-band around a pump tone frequency of the tunable TWPA.

In some implementations, the first interface is communicatively coupled to a first bias line, the second interface is communicatively coupled to a second bias line, and the third interface is communicatively coupled to a third bias line. The first bias line and the second bias line may be communicatively coupled to a first common bias line.

In some implementations, the tunable TWPA further comprises a second T stage, the second T stage comprising a fourth DC-SQUID, a fourth interface inductively communicatively coupled to the fourth DC-SQUID, the fourth interface operable to apply a fourth bias to the fourth DC-SQUID, a fifth DC-SQUID electrically communicatively coupled to the fourth DC-SQUID in series via a second center node, a fifth interface inductively communicatively coupled to the fifth DC-SQUID, the fifth interface operable to apply a fifth bias to the fifth DC-SQUID, a second resonator communicatively coupled to the second center node via a second coupling capacitance, the second resonator shunted to the ground, the second resonator comprising a second resonator capacitance, a second resonator inductance, and a sixth DC-SQUID, and a sixth interface inductively communicatively coupled to the sixth DC-SQUID, the sixth interface operable to apply a sixth bias to the sixth DC-SQUID, wherein the fourth bias and the fifth bias are adjustable to reduce the ripple in the gain versus frequency response of the tunable TWPA, and the sixth bias is adjustable to tune the position and the width of the stop-band around the pump tone frequency of the tunable TWPA.

The first bias line, the second bias line, the fourth bias line, and the fifth bias line may be communicatively coupled to a first common bias line. The third bias line and the sixth bias line may be communicatively coupled to a second common bias line. The third bias line and the sixth bias line may be communicatively coupled to a first common bias line.

A quantum processor may be summarized as comprising any of the above implementations of the tunable TWPA.

A tunable TWPA may be summarized as comprising a series array of tunable devices. At least one of the tunable devices may include a DC-SQUID. The DC-SQUID may comprise a superconducting loop, the superconducting loop comprising two electrically parallel paths each path of the two electrically parallel paths interrupted by a respective Josephson junction. The superconducting loop may include a twisted loop in a figure-of-eight configuration. In various of the above implementations, the tunable TWPA may further comprise an interface inductively communicatively coupled to the DC-SQUID, and operable to apply a flux bias to the DC-SQUID.

In some implementations, at least one of the tunable devices includes a loop of high kinetic inductance material. The loop of high kinetic inductance material may include at least one of niobium nitride, titanium nitride, niobium titanium nitride, molybdenum nitride, tungsten silicide, or granular aluminum. The loop of high kinetic inductance material may include a twisted loop in a figure-of-eight configuration. In various of the above implementations, the tunable TWPA may further comprise an interface inductively communicatively coupled to the loop of high kinetic inductance material, and operable to apply a flux bias to the loop of high kinetic inductance material.

In some implementations, at least one of the tunable devices includes a segment of high kinetic inductance material. The tunable TWPA may further comprise a bias line, wherein the segment of high kinetic inductance material is common to the at least one of the tunable devices and the bias line, and the bias line is operable to apply a current bias to the at least one of the tunable devices.

A quantum processor may be summarized as comprising any of the above implementations of the tunable TWPA.

In some implementations, at least one of the tunable devices includes at least three Josephson junctions in series. The tunable TWPA may further include a bias line, wherein the at least three Josephson junctions are common to the at least one of the tunable devices and the bias line, and the bias line is operable to apply a current bias to the at least one of the tunable devices.

A method of operation of a TWPA may be summarized as comprising electrically tuning a signal path length of a resonant structure of the TWPA to reduce a gain-limiting pump self-phase-modulation. In some implementations, electrically tuning a signal path length of a resonant structure of the TWPA to reduce a gain-limiting pump self-phase-modulation includes causing at least one of a change in an effective critical current, a change in an effective inductance, or a change to a non-linear operating region of at least one of a tunable device or a segment of the TWPA. In some implementations, electrically tuning a signal path length of a resonant structure of the TWPA to reduce a gain-limiting pump self-phase-modulation includes applying at least one of a flux bias or a current bias to at least one of a tunable device or a segment of the TWPA.

A method of increasing a bandwidth of a parametric amplifier may be summarized as comprising adjusting a pump tone of the parametric amplifier, reducing a ripple in a gain versus frequency response, and reducing a stop-band width. The parametric amplifier may comprise a tunable TWPA, the tunable TWPA may comprise a series array of tunable devices, and the reducing a ripple in a gain versus frequency response may include applying at least one of a flux bias or a current bias to at least one of the tunable devices of the series array of tunable devices. The applying at least one of a flux bias and a current bias to the at least one of the tunable devices may include applying a flux bias to a DC-SQUID. The parametric amplifier may comprise a tunable TWPA, the tunable TWPA may comprise a shunting resonator, the shunting resonator may comprise a DC-SQUID, and the reducing a stop-band width may include applying a flux bias to the DC-SQUID.

In other aspects, the features described above may be combined together in any reasonable combination as will be recognized by those skilled in the art.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn are not necessarily intended to convey any information regarding the actual shape of the particular elements and may have been solely selected for ease of recognition in the drawings.

FIG. 1 is a schematic diagram of a nonlinear transmission line, according to at least one exemplary implementation.

FIG. 2 is a schematic diagram of a T-stage of a nonlinear transmission line, according to at least one exemplary implementation.

FIG. 3 is a schematic diagram of a T-stage of a nonlinear transmission line, according to at least one exemplary implementation.

FIG. 4 is a schematic diagram of a T-stage of a nonlinear transmission line, according to at least one exemplary implementation.

FIG. 5 is a schematic diagram of a T-stage of a nonlinear transmission line, according to at least one exemplary implementation.

FIG. 6 is a schematic diagram of a T-stage of a nonlinear transmission line, according to at least one exemplary implementation.

FIGS. 7A and 7B are schematic diagrams of a portion of the T-stage of FIG. 4.

FIGS. 8A and 8B are schematic diagrams of a portion of the T-stage of FIG. 3.

FIG. 9A is a schematic drawing of a tunable TWPA, according to at least one exemplary implementation.

FIG. 9B is a flow chart of an example implementation of a method of operation of a tunable TWPA.

FIG. 10 is a block diagram of a readout system for a Gate-Model Quantum Computer (GMQC), according to at least one exemplary implementation.

FIG. 11 is a block diagram of a readout system for a superconducting circuit, according to at least one exemplary implementation.

FIG. 12 is a block diagram of a hybrid computing system, according to at least one exemplary implementation, including a digital computer and a quantum computer that may incorporate a tunable TWPA and/or FMR readout technology as described above.

FIG. 13 is a flow diagram of an example implementation of a method of operation to reduce a gain-limiting pump self-phase-modulation of a TWPA.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow; the word “comprising” is synonymous with “including,” and is inclusive or open-ended (i.e., does not exclude additional, unrecited elements or method acts).

Reference throughout this specification to “one implementation” or “an implementation” means that a particular feature, structure, or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

### Kinetic Inductance

Current flowing through a metal material in principle stores energy both in the magnetic field of that metal and in the kinetic energy of the charge carriers (e.g., the electrons or Cooper pairs). In non-superconducting metals, the charge carriers collide frequently with the lattice and lose their kinetic energy as Joule heating. This is also referred to as scattering, and quickly releases energy. However, in superconducting materials, scattering is substantially reduced, as the charge carriers are Cooper pairs which are protected against dissipation through scattering. This allows for superconducting materials to store energy in the form of kinetic inductance. This phenomenon allows kinetic inductance to efficiently store energy within the superconducting metal. Kinetic inductance is at least in part determined by the inertial mass of the charge carriers of a given material and increases as carrier density decreases. As the carrier density decreases, a smaller number of carriers must have a proportionally greater velocity in order to produce the same current. Materials that have high kinetic inductance for a given area (as defined below) are referred to as “kinetic inductance materials”, or “high kinetic inductance materials”.

Kinetic inductance materials are those that have a high normal-state resistivity and/or a small superconducting energy gap, resulting in a larger kinetic inductance per unit of area. In general, total inductance L of a superconducting material is given by L=L_{K}+L_{G}, where L_{G} is the geometric inductance and L_{K} is the kinetic inductance. The kinetic inductance of a superconducting film in near-zero temperatures is proportional to the effective penetration depth λ_{eff}. In particular, for a film with a given thickness t, the kinetic inductance of the film is proportional to the ratio of the length of the film L to the width of the film W, where length is in the direction of the current and width is orthogonal to length (note that both width and length are orthogonal to the dimension in which thickness is measured). That is,

$${L}_{K} ∼ {λ}_{eff} \frac{L}{W}$$

for a superconducting film with a given thickness. The kinetic inductance fraction of a material is characterized as

$$α = \frac{{L}_{k}}{{L}_{g} + {L}_{k}} .$$

A material considered to have high kinetic inductance would typically have α in the range of 0.1<α≤1. Materials with less than 10% of the energy stored as kinetic inductance would be considered traditional magnetic storage inductors with a small correction.

In some implementations it may be beneficial to attempt to maximize kinetic inductance in minimal volume. This may include attempting to minimize the width of the film, selecting a suitable material with a high effective penetration depth λ_{eff}, and selecting a length for the film which achieves the desired kinetic inductance. It may also be beneficial to attempt to minimize the thickness t of the material, subject to fabrication constraints, as for t<3λ_{eff(bulk)} (where λ_{eff(bulk)} is the effective penetration depth of the material in bulk, not thin-film), λ_{eff} increases at least approximately proportionately to 1/t². In some implementations, t<n·λ_{eff(bulk)}, where n is some value substantially less than 1 (e.g., 0.5, 0.1, 0.05, 0.01, etc.).

### Parametric Amplifiers

A quantum computer may include a low-noise amplifier. For example, a low-noise amplifier may be located at a 4K stage of a cryocooler of a superconducting quantum computer to amplify signals in NDRO (Non-Destructive Read Out) and FMRR (Frequency-Multiplexed Resonant Readout) circuits. In other implementations, a low-noise amplifier may be located at an output of a dispersive readout chain, for example, in a gate-model quantum computer.

A conventional approach is to locate a low-noise HEMT (high-electron-mobility transistor) amplifier at the 4K stage of the cryocooler of the superconducting quantum computer. It may be desirable to include a preamplifier with an even lower noise floor than the low-noise amplifier, and to locate the preamplifier at the mixing chamber (MXC) stage of the cryocooler of the superconducting quantum computer.

A superconducting low-noise preamplifier typically uses parametric amplification. A parametric amplifier is a nonlinear circuit in which one or more circuit parameters can vary with an input signal. For example, the input signal can be used to vary a reactance of a nonlinear component of the circuit. A parametric amplifier can be useful in situations where a conventional amplifier is unable to provide sufficient gain to detect a signal above a noise floor. Applications of a parametric amplifier can include quantum-limited amplification in the field of quantum information processing using superconducting circuits.

A parametric amplifier can provide adjustable amplification and up/down conversion of an input analog signal, for example, by applying a sinusoidal signal (generally referred to as a pump signal or a pump tone) to a nonlinear reactive circuit element. The pump signal can cause a reactance of the nonlinear reactive circuit element to vary sinusoidally at the same frequency as a frequency of the pump signal.

Conventional parametric amplifiers are typically narrow-band amplifiers, and may not be compatible with a readout circuit, for example, an FMRR circuit.

Some implementations of parametric amplifiers include a modified Traveling Wave Parameter Amplifier (TWPA). Some implementations of a TWPA are broadband amplifiers and can be tuned by adjusting an amplitude and frequency of the pump signal.

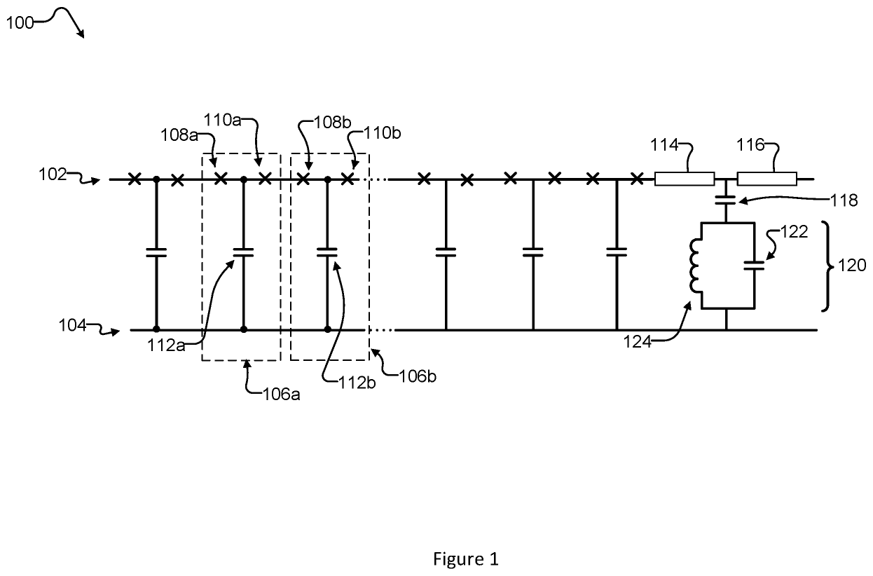

A TWPA may include a nonlinear transmission line comprising a lumped-element transmission line in which at least some inductances have been replaced by Josephson junctions. Some implementations include multiple T-stages, each T-stage including a capacitance and two Josephson junctions, one upstream and one downstream from the capacitance. This is described in more detail below with reference to FIG. 1.

A shortcoming of a conventional TWPA is that pump self-phase-modulation can limit an achievable gain. One approach to mitigate the shortcoming is to insert an additional phase shift to the pump signal by, for example, adding at least two capacitively-coupled resonant shunts to ground, where the shunts are spaced by half a wavelength of the pump signal. The resonant frequency of the shunts can be selected to be sufficiently close to the desired pump frequency, and the pump frequency can be suitably fine-tuned during operation of the TWPA.

In one implementation of a TWPA for an FMRR circuit, a critical current of the Josephson junctions is chosen to be 10 μA, and the shunt capacitance for a linear transmission line of characteristic impedance Z₀ (usually 50Ω) is chosen to be 26 fF. A single T-stage, including vias and contacts, can be fabricated within an area on an integrated circuit of, for example, 15 μm on a side. The TWPA includes, for example, 48 T-stages and is 4.5 cm in length in total, and can be arranged in a meander on an integrated chip that is, for example, 1 cm on a side. The coupling capacitance is, for example, 5 fF.

### Non-Linear Transmission Line

FIG. 1 is a schematic diagram of a nonlinear transmission line 100, according to at least one exemplary implementation. Nonlinear transmission line 100 includes two conductors 102 and 104, and an array of T-stages (for example, T-stages 106a and 106b) collectively referred to as T-stages 106. Each T-stage of T-stages 106 includes a respective pair of Josephson junctions (for example, Josephson junctions 108a and 110a of T-stage 106a, and Josephson junctions 108b and 110b of T-stage 106b). The Josephson junctions are collectively referred to as Josephson junctions 108 and 110. Each T-stage of T-stages 106 further includes a respective capacitor (for example, capacitor 112a of T-stage 106a and capacitor 112b of T-stage 106b) between conductor 102 and conductor 104. The capacitors are collectively referred to as capacitors 112. In some implementations, conductor 104 is communicatively coupled to a ground, and capacitors 112 are referred to as shunting capacitors 112.

Nonlinear transmission line 100 further includes impedances 114 and 116, a capacitance 118, and a shunting resonator 120. Shunting resonator 120 includes a resonator capacitance 122 and a resonator inductance 124.

A disadvantage of the nonlinear transmission line of FIG. 1 is that the pump tone frequency and the pump tone power may be static, and hence not dynamically variable. It can be desirable (for example, to support frequency multiplexing) to be able to dynamically vary the pump tone frequency. In some situations, it can be desirable to be able to dynamically vary the pump tone frequency while retaining a desired gain.

Varying the pump tone frequency of the nonlinear transmission line of FIG. 1 may not be possible owing to the presence of a narrow-band filter and/or a narrow-band signal generator upstream. It may not be possible to adjust the pump tone frequency to achieve a desired gain of the parametric amplifier. Without being able to dynamically adjust the pump tone frequency, the parametric amplifier must be designed and fabricated to have the desired pump tone frequency and gain. Variations in fabrication, for example, can lead to unwanted deviations from the desired pump tone frequency and gain.

During operation of a parametric amplifier comprising a nonlinear transmission line with a serial array of Josephson junctions (for example, nonlinear transmission line 100 of FIG. 1), the Josephson junctions can be driven into a non-linear region by driving the pump tone at a pump tone power that exceeds a threshold pump tone power. Varying the threshold pump tone power of the nonlinear transmission line of FIG. 1 may not be possible.

The technology described in the present application can at least reduce gain-limiting pump self-phase-modulation in a TWPA at a desired pump tone frequency by electrically tuning a signal path length of a resonant structure of the TWPA.

An electric current in a superconductive material above which the superconductive material is normal (i.e., not superconducting) and below which the superconductive material is superconducting, at a specified temperature and in the absence of an external magnetic field, is referred to in the present application as a critical current.

The critical current of unbiased Josephson junctions 108 and 110 of nonlinear transmission line 100 of FIG. 1 is fixed. Using technology described in the present application, the critical current can be adjusted by applying a DC flux bias and/or a DC current bias. The DC flux bias and/or DC current bias can set an operating point, either a steady state flux and/or a steady state current when no signal is applied, or a mean amplitude of the flux and/or the current.

The technology described below includes a non-linear transmission line comprising a series array of current-biased Josephson junctions, a series array of flux-biased DC-SQUIDs, a series array of flux-biased, high kinetic inductance (or equivalently low-carrier-density) loops, and/or at least one high kinetic inductance, current-biased segment, which substitute for a series array of unbiased Josephson junctions (e.g., Josephson junctions 108 and 110 of FIG. 1). A high kinetic inductance material is one in which at least 10% of the energy stored in the material may be stored as a kinetic inductance. A high kinetic inductance material may include, but is not limited to, niobium nitride (NbN), titanium nitride (TiN), niobium titanium nitride (NbTiN), molybdenum nitride (MoN), tungsten silicide (WSi), and/or granular aluminum (Al). High kinetic inductance materials are discussed in further detail above.

An effective critical current of the devices and/or segments in the serial array can be adjusted by applying either a DC flux bias or a current bias. An applied flux bias or current bias can cause a change in an effective inductance of at least a segment (for example, a T-stage) of a nonlinear transmission line, which in turn can cause a change in a resonant frequency of shunting circuits. A flux bias or current bias applied to a device (for example, a Josephson junction) can also bring the device closer to its non-linear operating region, which in turn can reduce the threshold pump tone power described above.

In some implementations, a single bias line can provide the same bias to multiple devices (for example, multiple Josephson junctions). In some implementations, multiple bias lines can provide separate biases to single devices and/or multiple devices. In some implementations, using a bias line to bias a single device can improve a degree of control over the effective inductance, which in turn may advantageously: a) at least improve a control of an output gain, b) help to shape a gain versus frequency response, and/or c) improve a uniformity of response between segments (for example, T-stages), and/or to mitigate a non-uniformity caused, for example, by an external magnetic field gradient.

A loop with a large area can introduce an unwanted bias in the presence of an external magnetic field. In some implementations, the unwanted bias can be at least mitigated by configuring the loop in a gradiometric pattern resembling a figure-of-eight. A gradiometric design can eliminate, or at least reduce, an unwanted flux bias caused by an external magnetic field, provided the external magnetic field has a sufficiently low field-gradient and presents a sufficiently uniform magnetic field to the figure-of-eight.

One approach to implementing the technology described in the present application includes the following:
Establishing specifications for: a) desired pump tone power, b) pump tone frequency range, c) transmission line impedance, and d) an upper bound on a critical current of a segment of the transmission line.
Determining a junction area for Josephson junctions based on an achievable current density
Determining a shunting capacitance value using Z₀=√(L/C), where Z₀ is the characteristic impedance, L is the inductance, and C is the shunting capacitance, and
Determining a resonant frequency of the unbiased shunting circuits to match as closely as possible an upper bound to the desired pump tone frequency range.

The technology described in the present application may be implemented within a fabric of a processor (i.e., on the processor chip), and/or off-chip, for example, as a microwave source or as a stand-alone device communicatively coupled to an input and/or output of an FMR readout chain.

The technology described in the present application includes an in-situ dynamically-tunable characteristic impedance, and can be used as both a microwave switch and/or a parametric amplifier.

### Example Implementations of T-Stages for a Non-Linear Transmission Line

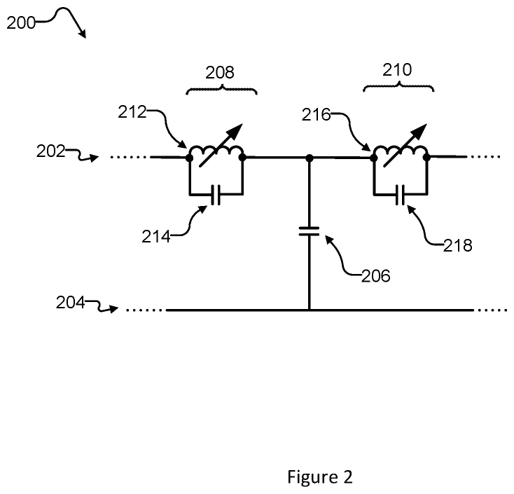

FIG. 2 is a schematic diagram of a T-stage 200 of a nonlinear transmission line, according to at least one exemplary implementation. T-stage 200 includes conductors 202 and 204, a capacitance 206 electrically coupled between conductors 202 and 204, and elements 208 and 210, one upstream and one downstream of capacitance 206. Elements 208 and 210 schematically illustrate circuits that are electrically equivalent to Josephson junctions with a tunable critical current.

Element 208 includes a variable inductance 212 and a capacitance 214 in parallel with variable inductance 212. Variable inductance 212 may be varied, for example, by an applied flux bias and/or current bias (not shown in FIG. 2). Similarly, element 210 includes a variable inductance 216 and a capacitance 218 in parallel with variable inductance 216, and variable inductance 216 may be varied, for example, by an applied flux bias and/or current bias.

In some implementations of nonlinear transmission line 100 of FIG. 1, at least some of T-stages 106 are replaced by tunable T-stages, for example, T-stage 200 of FIG. 2.

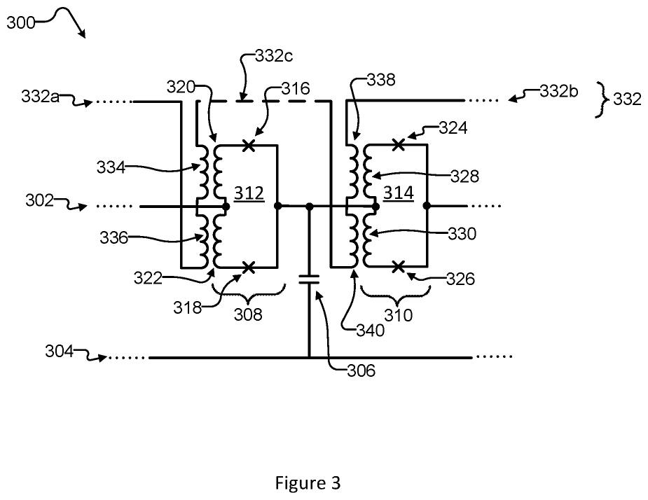

FIG. 3 is a schematic diagram of a T-stage 300 of a nonlinear transmission line, according to at least one exemplary implementation. T-stage 300 includes conductors 302 and 304, and a capacitance 306 electrically coupled between conductors 302 and 304. T-stage 300 also includes tunable devices 308 and 310. Each of tunable devices 308 and 310 includes a DC-SQUID 312 and 314, respectively. Each of DC-SQUIDs 312 and 314 includes a superconducting loop comprising two electrically parallel paths each interrupted by a respective Josephson junction.

DC-SQUID 312 includes Josephson junctions 316 and 318, and inductances 320 and 322. In some implementations, inductances 320 and 322 are intrinsic to Josephson junctions 316 and 318, respectively. Similarly, DC-SQUID 314 includes Josephson junctions 324 and 326, and inductances 328 and 330. In some implementations, inductances 328 and 330 are intrinsic to Josephson junctions 324 and 326, respectively.

DC-SQUID 312 is communicatively coupled to a bias line 332a, and DC-SQUID 314 is communicatively coupled to a bias line 332b. In some implementations, DC-SQUIDs 312 and 314 are communicatively coupled to a common bias line 332 comprising bias lines 332a and 332b and bias line segment 332c (shown as a dashed line in FIG. 3).

Bias line 332a and common bias line 332 include inductive interfaces 334 and 336 to inductances 320 and 322, respectively. Similarly, bias line 332b and common bias line 332 include inductive interfaces 338 and 340 to inductances 328 and 330, respectively. Common bias line 332 is operable to provide a bias to DC-SQUIDs 312 and 314.

In some implementations of nonlinear transmission line 100 of FIG. 1, at least some of T-stages 106 are replaced by tunable T-stages, for example, T-stage 300 of FIG. 3.

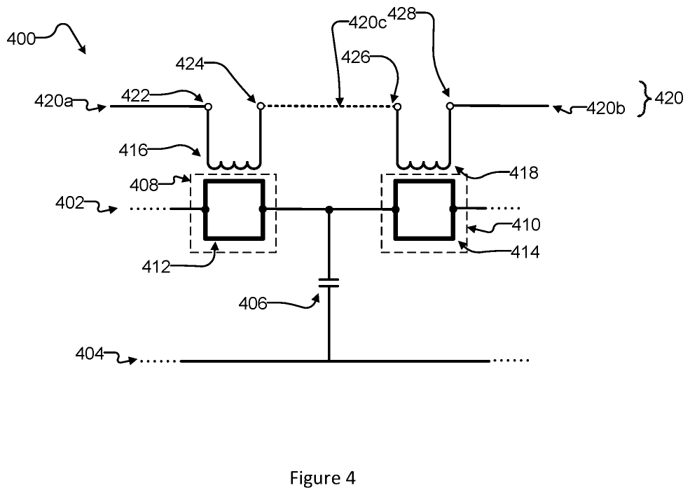

FIG. 4 is a schematic diagram of a T-stage 400 of a nonlinear transmission line, according to at least one exemplary implementation. T-stage 400 includes conductors 402 and 404, and a capacitance 406 electrically coupled between conductors 402 and 404. T-stage 400 also includes tunable devices 408 and 410. Each of tunable devices 408 and 410 includes a loop of high kinetic inductance material 412 and 414, respectively. Each loop of high kinetic inductance material 412 and 414 can be tuned via an inductance interface 416 and 418, respectively.

Inductive interface 416 is communicatively coupled to a bias line 420a at terminals 422 and 424, and inductive interface 418 is communicatively coupled to a bias line 420b at terminals 426 and 428. In some implementations, bias lines 420a and 420b are communicatively coupled by line 420c (shown as a dashed line in FIG. 4) to form a common bias line 420.

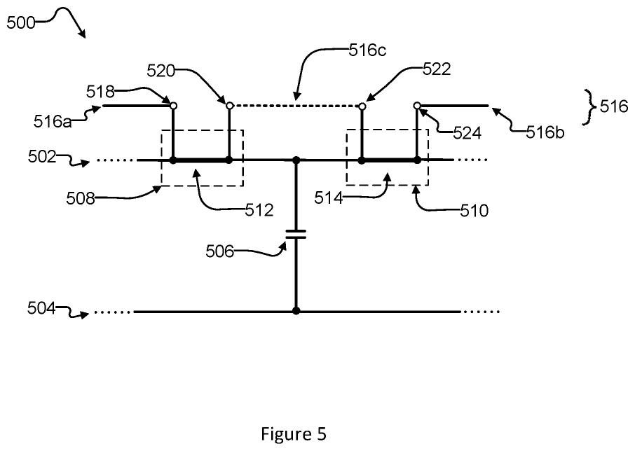

FIG. 5 is a schematic diagram of a T-stage 500 of a nonlinear transmission line, according to at least one exemplary implementation. T-stage 500 includes conductors 502 and 504, and a capacitance 506 electrically coupled between conductors 502 and 504. T-stage 500 also includes tunable devices 508 and 510. Each of tunable devices 508 and 510 includes a segment of high kinetic inductance material 512 and 514, respectively.

Each segment of high kinetic inductance material 512 and 514 can be tuned by electrically communicatively coupling each segment 512 and 514 to a respective bias line. Segment 512 is communicatively coupled to bias line 516a at terminals 518 and 520, and segment 514 is communicatively coupled to bias line 516b at terminals 522 and 524. In some implementations, bias lines 516a and 516b are communicatively coupled by line 516c (shown as a dashed line in FIG. 5) to form a common bias line 516. Segment 512 is common to conductor 502 and bias line 516a, and segment 514 is common to conductor 502 and bias line 516b.

T-Stage with Josephson Junctions

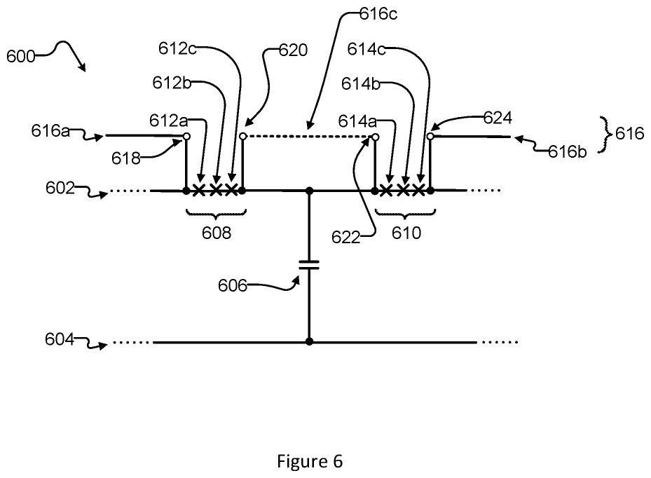

FIG. 6 is a schematic diagram of a T-stage 600 of a nonlinear transmission line, according to at least one exemplary implementation. T-stage 600 includes conductors 602 and 604, and a capacitance 606 electrically coupled between conductors 602 and 604. T-stage 600 also includes tunable devices 608 and 610. Tunable device 608 includes Josephson junctions 612a, 612b, and 612c (collectively referred to as Josephson junctions 612). Similarly, tunable device 610 includes Josephson junctions 614a, 614b, and 614c (collectively referred to as Josephson junctions 614). In some implementations, at least one of tunable devices 608 and 610 includes more than three Josephson junctions.

Each device 608 and 610 can be tuned by electrically communicatively coupling each device 608 and 610 to a respective bias line. Device 608 is communicatively coupled to a bias line 616a at terminals 618 and 620, and device 610 is communicatively coupled to a bias line 616b at terminals 622 and 624. In some implementations, bias lines 616a and 616b are communicatively coupled by line a 616c (shown as a dashed line in FIG. 6) to form a common bias line 616. Josephson junctions 612 of device 608 are common to (and in series with) conductor 602 and bias line 616a, and Josephson junctions 614 of device 610 are common to (and in series with) conductor 602 and bias line 616b.

### Figure-of-Eight Configurations

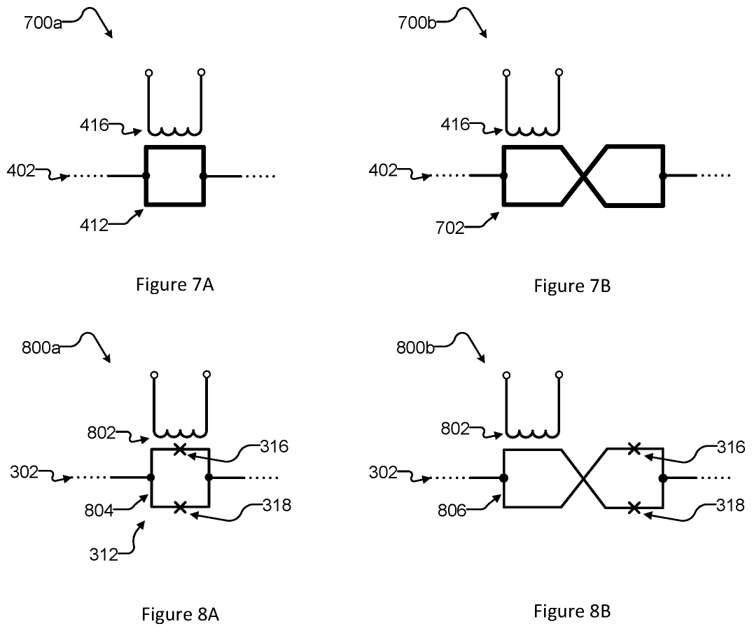

FIG. 7A is a schematic diagram of a portion 700a of T-stage 400 of FIG. 4. Portion 700a includes conductor 402, loop of high kinetic inductance material 412, and inductive interface 416. In FIG. 7B, loop 412 has been replaced by a twisted loop 702 in a figure-of-eight configuration. The portions of high kinetic inductance material at crossing point of the twisted loop 702 do not contact each other, for example residing in different planes, so there is a single continuous loop in the figure-of-eight configuration rather than two loops that are joined together.

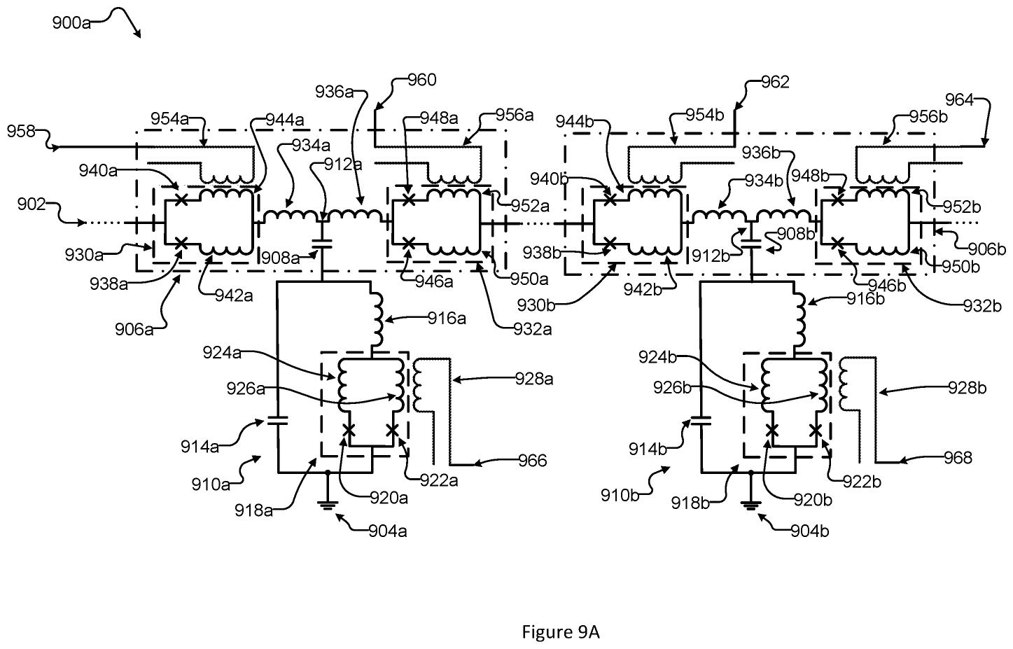

FIG. 8A is a simplified schematic diagram of a portion 800a of T-stage 300 of FIG. 3. Portion 800a includes conductor 302, DC-SQUID 312, and an inductive interface 802 that includes inductive interfaces 320 and 322 of FIG. 3. DC-SQUID 312 includes Josephson junctions 316 and 318, and DC-SQUID loop 804. In FIG. 8B, DC-SQUID loop 804 has been replaced by a twisted loop 806 in a figure-of-eight configuration. The portions of high kinetic inductance material at crossing point of the twisted loop 806 do not contact each other, for example residing in different planes, so there is a single continuous loop in the figure-of-eight configuration rather than two loops that are joined together.

### Tunable TWPA

Superconducting gate-model quantum computing (GMQC) systems may include a parametric amplifier to increase a signal-to-noise ratio (SNR) of resonator-coupled qubit measurements. Implementations may be based on distributed-element and/or lumped-element implementations of resonant circuits.

A challenge with distributed-element implementations is that they typically involve a large on-chip footprint (i.e., take up valuable real estate on the chip). Existing implementations typically include a high-power microwave pump tone. Since microwave-line wiring can be challenging, on-chip and/or off-chip, it can be desirable for a readout system to use only DC bias lines to provide tuning and amplification energy. Unfortunately, power consumption and power dissipation considerations may preclude the use of existing implementations, which have only DC bias lines, as narrow-band amplifiers at low temperatures (e.g., at temperatures below 4K). A typical conventional amplifier having only DC bias lines can dissipate ˜1 nW of power. Dissipating even a few hundred pW of power can be challenging in a scalable quantum processor.

Conventional technology typically includes amplifiers that can be fabricated in a single layer with a limited number of control lines. Another approach is to use a multi-layer fabrication stack, for example, a niobium (Nb) trilayer stack. An example implementation of a Nb trilayer stack is described in SUPERCONDUCTOR INTEGRATED CIRCUIT FABRICATION TECHNOLOGY, L. A. Abelson and G. L. Kerber, Proceedings of the IEEE, Vol. 92, No. 10, (2004). It can be challenging even with a multi-layer stack to achieve sufficient gain over a readout resonator band. In one example implementation, a gain of 20 dB over a resonator band of 4 GHz to 8 GHz is desirable.

The amount of ripple and the center frequency of the resonator band can be tuned by changing a critical current of Josephson junctions in the transmission line. One approach is to: a) first replace the single Josephson junctions (e.g., Josephson junctions 108 and 110 of FIG. 1) by DC-SQUIDs, each DC-SQUID tunable by an applied magnetic flux, where the DC-SQUIDs form an array equivalent to an array of Josephson junctions, b) adjust a critical current of the Josephson junctions of the equivalent array of Josephson junctions, and then c) adjust a capacitance shunting a respective center node or pin of each T-stage to a ground of the transmission line. In one implementation, a center frequency of the tunable TWPA is adjustable between 1 GHz and 7 GHz. A shortcoming of this approach is that the gain as a function of frequency is a narrower and steeper curve than desired, for at least some applications of the technology.

Another approach is to include at least one compensating LC resonator. The approach is also referred to in the present application as resonant phase matching (RPM). While the overall gain can be improved by RPM, another consequence of RPM is that a stop-band opens up around the pump tone frequency, suppressing gain for frequencies on either side of, and close to, the pump tone frequency. Decreasing the stop-band width would improve performance by opening up available bandwidth.

Performance can also be affected by which dielectric is used, for example, using silicon nitride (SiN) or amorphous silicon hydride (a-SiH) as a capacitor dielectric can reduce an insertion loss relative to using silicon oxide (SiOx).

The technology described in the present application includes adding tunability to both: a) the transmission line Josephson junctions, and b) the phase-matching LC resonators.

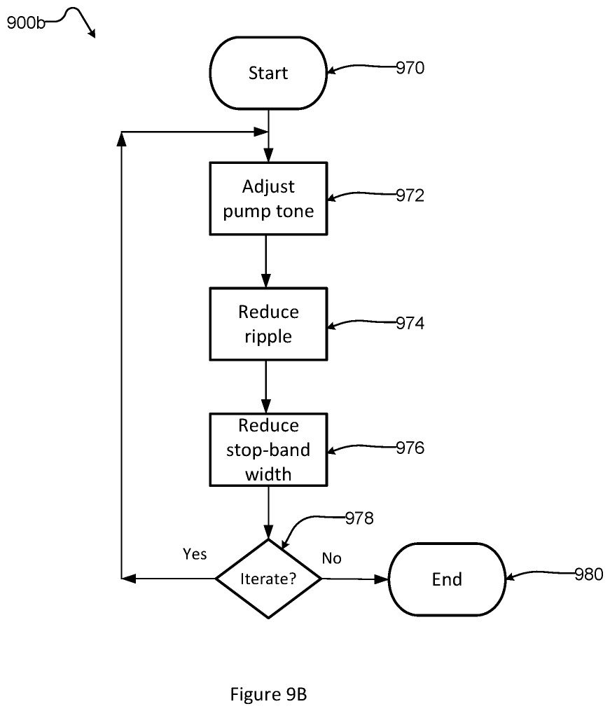

FIG. 9A is a schematic drawing of a tunable TWPA 900a, according to at least one exemplary implementation. Tunable TWPA 900a includes a transmission line conductor 902 and transmission line grounds 904a and 904b (collectively referred to as ground 904).

TWPA 900a includes multiple T-stages, for example, T-stages 906a and 906b.

T-stage 906a includes a shunting capacitance 908a. TWPA 900a includes a phase-matching resonator 910a in series between a center node or pin 912a and ground 904a. Resonator 910a includes a capacitance 914a, an inductance 916a, and a DC-SQUID 918a. DC-SQUID 918a includes Josephson junctions 920a and 922a, and inductances 924a and 926a. T-stage 906a includes an interface 928a inductively communicatively coupleable to DC-SQUID 918a.

T-stage 906a also includes DC-SQUIDs 930a and 932a in series with conductor 902, DC-SQUID 930a upstream and DC-SQUID 932a downstream of center node or pin 912a. DC-SQUIDs 930a and 932a are electrically communicatively coupled to center node or pin 912a by inductances 934a and 936a, respectively.

DC-SQUID 930a includes Josephson junctions 938a and 940a, and inductances 942a and 944a. DC-SQUID 932a includes Josephson junctions 946a and 948a, and inductances 950a and 952a.

T-stage 906a includes interfaces 954a and 956a inductively communicatively coupleable to DC-SQUIDs 930a and 932a, respectively.

Similarly, T-stage 906b includes a shunting capacitance 908b. TWPA 900a includes a phase-matching resonator 910b in series between a center node or pin 912b and ground 904b. Resonator 910b includes a capacitance 914b, an inductance 916b, and a DC-SQUID 918b. DC-SQUID 918b includes Josephson junctions 920b and 922b, and inductances 924b and 926b. T-stage 906b includes an interface 928b inductively communicatively coupleable to DC-SQUID 918b.

T-stage 906b also includes DC-SQUIDs 930b and 932b in series with conductor 902, DC-SQUID 930b upstream and DC-SQUID 932b downstream of center node or pin 912b. DC-SQUIDs 930b and 932b are electrically communicatively coupled to center node or pin 912b by inductances 934b and 936b, respectively.

DC-SQUID 930b includes Josephson junctions 938b and 940b, and inductances 942b and 944b. DC-SQUID 932b includes Josephson junctions 946b and 948b, and inductances 950b and 952b.

T-stage 906b includes interfaces 954b and 956b inductively communicatively coupleable to DC-SQUIDs 930b and 932b, respectively.

In operation, a bias applied to DC-SQUIDs 930a, 932a, 930b, and 932b via interfaces 954a, 956a, 954b, and 956b, respectively, can be used to adjust a drive impedance to reduce ripple in the gain versus frequency response of TWPA 900a. A bias applied to DC-SQUIDs 910a and 910b via interfaces 928a and 928b, respectively, can be used to adjust a position and width of a stop-band around the pump tone frequency of TWPA 900a.

A bias can be applied to DC-SQUIDs 930a, 932a, 930b, 932b, 910a, and 910b by bias lines 958, 960, 962, 964, 966, and 968, respectively. In some implementations, some of lines 958, 960, 962, and 964 are in common with each other. In some implementations, lines 966 and 968 are in common with each other.

To tune a tunable TWPA (for example, tunable TWPA 900a of FIG. 9A), an iterative process can be used. The tunable TWPA may be a tunable TWPA of a parametric amplifier, for example. The iterative process can include the following acts:
adjusting a pump tone frequency;
reducing a ripple in the gain versus frequency response; and
reducing a stop-band width.

Adding tunability to the phase-matching resonators as described above can provide control of the stop-band around the pump tone frequency in the gain versus frequency response, and improve performance by increasing available bandwidth.

FIG. 9B is a flow diagram of an example implementation of a method of operation 900b of a tunable TWPA.

Method 900b includes acts 970 to 980, though those of skill in the art will appreciate that in alternative embodiments certain acts may be omitted and/or additional acts may be added.

Method 900b starts at 970, for example in response to an initiation of the tuning of a TWPA. At 972, a controller or an operator of the TWPA adjusts a pump tone of the TWPA. At 974, the controller or the operator reduces a ripple. At 976 the controller or the operator reduces a stop-band width.

Method 900b can be iterative. At 978, the controller or operator decides whether to iterate the process. If yes, then control of method 900b returns to 972. Otherwise, method 900b ends at 980.

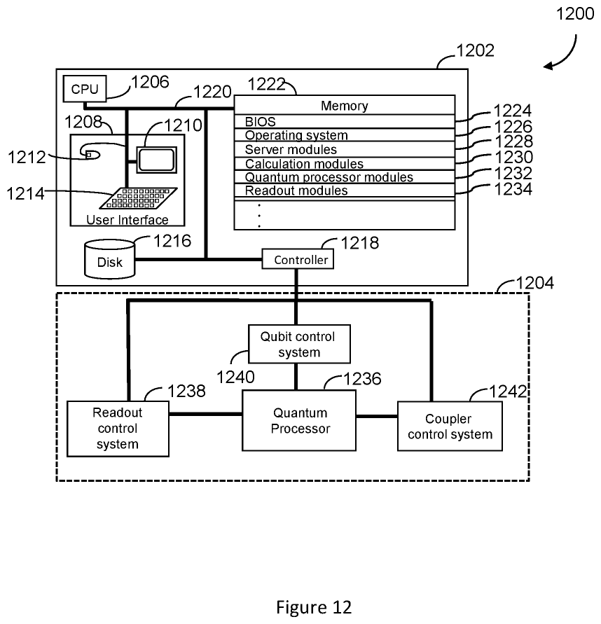

Method 900b can, in some implementations, be performed by a hybrid computing system such as hybrid computing system 1200 of FIG. 12. In some implementations, method 1300 may be performed by digital processor 1202 sending signals to quantum processor 1204, such as through controller 1218. Control commands may be provided by digital processor 1202 to cause tuning of a tunable TWPA such as tunable TWPA 900a, for example as part of control or readout systems of quantum processor 1204.

Those of skill in the art will appreciate that the illustrated order of the acts is shown for exemplary purposes only and may change in alterative embodiments.

### GMQC Readout System

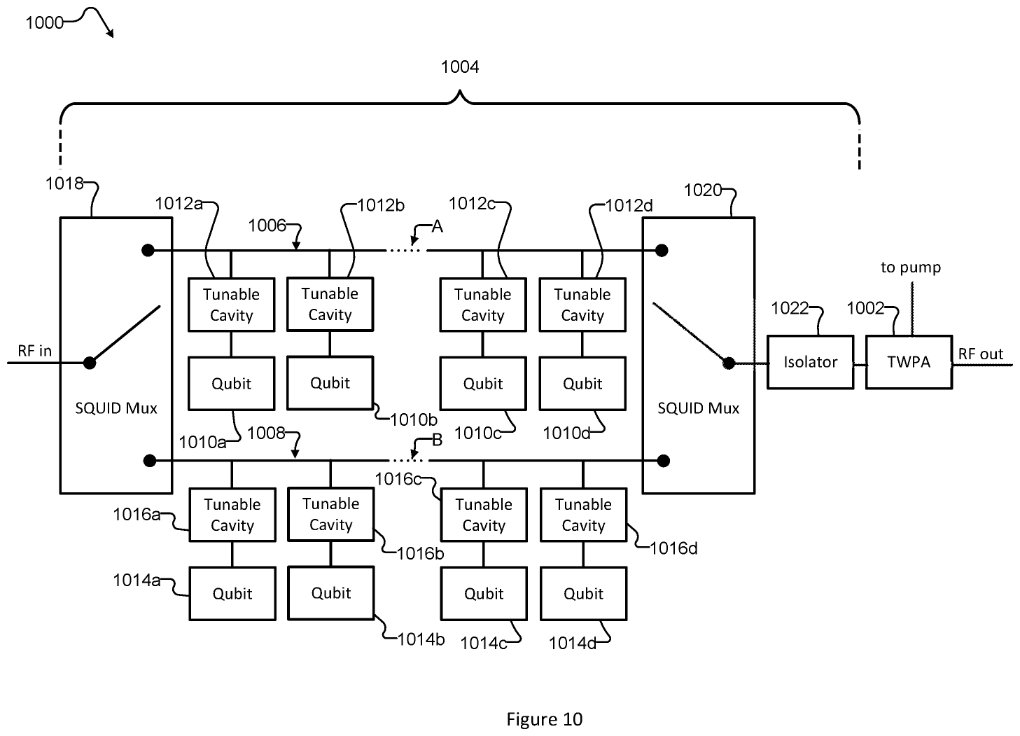

FIG. 10 is a block diagram of a readout system 1000 for a Gate-Model Quantum Computer (GMQC), according to at least one exemplary implementation. Readout system 1000 includes TWPA 1002. TWPA 1002 may be a tunable TWPA (for example, tunable TWPA 900a of FIG. 9).

Readout system 1000 includes a dispersive readout chain 1004. Readout chain 1004 includes RF (radio frequency) lines 1006 and 1008. Readout chain 1004 includes qubits 1010a, 1010b, 1010c, and 1010d (collectively referred to as qubits 1010) communicatively coupled to RF line 1006 via tunable cavities 1012a, 1012b, 1012c, and 1012d (collectively referred to as tunable cavities 1012), respectively. Similarly, readout chain 1004 includes qubits 1014a, 1014b, 1014c, and 1014d (collectively referred to as qubits 1014) communicatively coupled to RF line 1008 via tunable cavities 1016a, 1016b, 1016c, and 1016d (collectively referred to as tunable cavities 1016), respectively.

Though readout system 1000 of FIG. 10 includes four qubits 1010 and four tunable cavities 1012 communicatively coupled to RF line 1006, and four qubits 1014 and four tunable cavities 1016 communicatively coupled to RF line 1008, a person of skill in the art will appreciate that more than four qubits and four cavities may be communicatively coupled to RF line 1006 and/or RF line 1008. This is also indicated in FIG. 10 by dotted line segments A and B. In other implementations, a readout system has fewer than four qubits and four tunable cavities communicatively coupled to each RF line.

Readout chain 1004 also includes an input SQUID multiplexer 1018, an output SQUID multiplexer 1020, and an isolator 1022 communicatively coupled to output SQUID multiplexer 1020. Input SQUID multiplexer 1018 is operable to receive an RF input. Output SQUID multiplexer is operable to transmit an RF output via isolator 1022 and TWPA 1002. TWPA 1002 is operable to receive a pump tone as described above.

### FMR Readout System

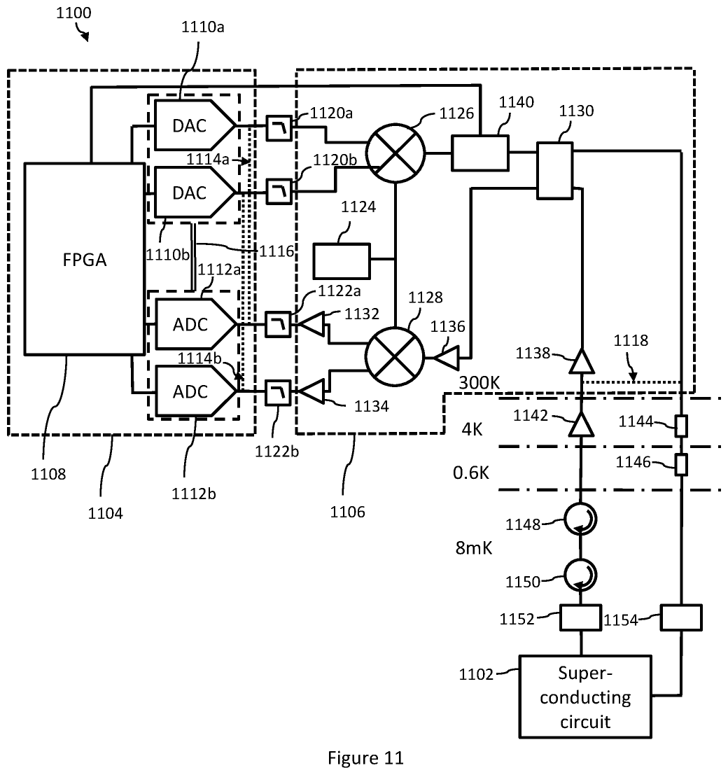

FIG. 11 is a block diagram of a readout system 1100 for a superconducting circuit 1102, according to at least one exemplary implementation. Readout system 1100 of FIG. 11 is also referred to in the present application as an FMR Readout.

In the illustrated implementation, superconducting circuit 1102 comprises one or more superconducting resonators (not shown in FIG. 11). In the illustrated implementation, superconducting circuit 1102 comprises a superconducting quantum processor (e.g., a quantum annealer). In other implementations, superconducting circuit 1102 comprises a superconducting classical processor.

Readout system 1100 comprises a digital board 1104 and a microwave board 1106. Digital board 1104 comprises a Field Programmable Gate Array (FPGA) 1108 (such as a Xilinx Kintex-7 FPGA from Xilinx, Inc. of San Jose, CA, US), two Digital-to-Analog Converters (DACs) 1110a and 1110b (collectively referred to as DACs 1110), and two Analog-to-Digital Converters (ADCs) 1112a and 1112b (collectively referred to as ADCs 1112). In other embodiments, digital board 1102 comprises two FPGAs, one providing output to DACs 1110, and the other providing output to ADCs 1112. In one implementation, each of DACs 1110 can be implemented using an Analog Devices 9129 DAC which is a dual-channel 14-bit DAC operating at up to about 5.6 Gsps (Giga samples per second). ADCs 1112 can be implemented using a multi-channel device such as an E2V EV10AQ190 which is a quad-channel 10-bit ADC capable of operating in dual-channel mode at up to about 2.5 Gsps.

Readout system 1100 advantageously enables independent addressing of the two side-bands of the FMR spectrum. The complex received signal is given by:

$$x ( n ) = I ( n ) + jQ ( n )$$

where I(n) is the output of ADC 1112a and Q(n) is the output of ADC 1112b.

The FMR spectrum is computed as follows:

$${X}_{k} = \frac{1}{N} {\sum }_{n = 0}^{N - 1} x ( n ) [ cos ( \frac{2 π kn}{N} ) - j sin ( \frac{2 π kn + 2 π k τ}{N} ) ]$$

for k∈0, 1, 2, 3 . . . . N−1, where N is a number of samples of the complex received signal. The second term in the argument of the sine function depends on t and can be used to compensate for the phase imbalance between the two mixer channels that results from the analog nature of the mixer.

Digital board 1104 further comprises two loopback lines 1114a and 1114b, and a sync/clock connection 1116. Loopback line 1114a connects the output of DAC 1110a to the input of ADC 1112a. Loopback line 1114b connects the output of DAC 1110b to the input of ADC 1112b.

Microwave subsystem or microwave board 1106 further comprises a loopback line 1118. Loopback line 1118 connects the input and output to cryogenic subsystem (not shown in FIG. 11) used to cool superconducting circuit 1102 to temperatures as low as a few mK.

Loopback lines 1114a and 1114b on digital board 1104, and loopback line 1118 on microwave board 1106 are optional, and used, for example, to bypass other elements of readout system 1100.

Readout system 1100 further comprises two reconstruction filters 1120a and 1120b, and two anti-aliasing filters 1122a and 1122b. Reconstruction filters 1120a and 1120b are low-pass analog filters that can be used to produce a band-limited analog signal from a digital input. Anti-aliasing filters 1122a and 1122b are low-pass analog filters that can be used to band-limit a received signal in order to satisfy or approximately satisfy the sampling theorem over a band of interest.

Microwave board 1106 comprises a Voltage-Controlled Oscillator (VCO)/Phase Locked Loop (PLL) 1124 which provides a reference microwave signal, mixers 1126 and 1128, and programmable attenuators 1130. Microwave board 1106 further comprises amplifiers 1132, 1134, 1136 and 1138. Amplifiers 1132, 1134, 1136 and 1138 can be used to provide level control on the signal received from superconducting circuit 1102. In one implementation, amplifier 1136 can be a Miteq AFS4-02000800-30-22P-4, and amplifier 1138 can be a Miteq AFD3-040080-28-LN low-noise amplifier. These exemplary amplifiers are available from Miteq Inc., of Hauppauge, NY, US. Microwave board 1106 further comprises a microwave switch 1140 controlled by a signal from FPGA 1108 on digital board 1104.

In one implementation, mixers 1126 and 1128 are complex mixers.

The illustrated readout system 1100 further comprises amplifier 1142, attenuators 1144 and 1146, circulators 1148 and 1150, and DC blocks 1152 and 1154. DC blocks 1152 and 1154 are used as a thermal break on each of the input and output lines to superconducting circuit 1102.

In one implementation, amplifier 1142 can be a LNF-3611-28-04000800 low-noise cryogenic amplifier. Amplifier 1142 and attenuator 1144 can operate at 4 K. Attenuator 1146 can operate at 0.6 K. Circulators 1148 and 1150, and DC blocks 1153 and 1154, can operate at 8 mK. In one implementation, cryogenic circulators 1148 and 1150 can each be implemented using a Quinstar CTH0408KC, and DC blocks 1152 and 1154 can each be implemented using an Aeroflex/Inmet 8039.

Using 60 resonators and a bandwidth of 2.5 GHZ, a data rate of approximately 600 Mbps can be achieved for a shift register stage (SRS) operation time of 25 ns.

An FMR readout (for example, readout system 1100 of FIG. 11) may be used in a quantum annealer, for example. A tunable TWPA (for example, tunable TWPA 900a of FIG. 9) may be incorporated, for example, at a cold output of an FMR Readout chain of a quantum annealer.

### Hybrid Quantum Computing System

FIG. 12 is a block diagram of a hybrid computing system 1200, according to at least one exemplary implementation, including a digital computer 1202 and a quantum computer 1204, that may incorporate a tunable TWPA and/or FMR readout technology as described above.

Digital computer 1202 comprises CPU 1206, user interface elements 1208, 1210, 1212 and 1214, disk 1216, controller 1218, bus 1220 and memory 1222. Memory 1222 comprises modules 1224, 1226, 1228, 1230, 1232 and 1234.

Quantum computer 1204 comprises quantum processor 1236, readout control system 1238, qubit control system 1240 and coupler control system 1242. Quantum computer 1204 can incorporate FMR technology comprising superconducting resonators. Computing system 1200 can comprise a readout system such as readout system 1100 of FIG. 11.

### Reducing a Gain-Limiting Self-Phase-Modulation

In operation, a gain-limiting pump self-phase-modulation of a TWPA may be reduced by electrically tuning a signal path length of a resonant structure of the TWPA. Reducing the gain-limiting pump self-phase-modulation by electrically tuning a signal path length of a resonant structure of the TWPA may include causing at least one of a change in an effective critical current, a change in an effective inductance, or a change to a non-linear operating region of at least one of a tunable device or a segment of the TWPA. Reducing the gain-limiting pump self-phase-modulation of the TWPA may include applying at least one of a flux bias or a current bias to at least one of a tunable device or a segment of the TWPA.

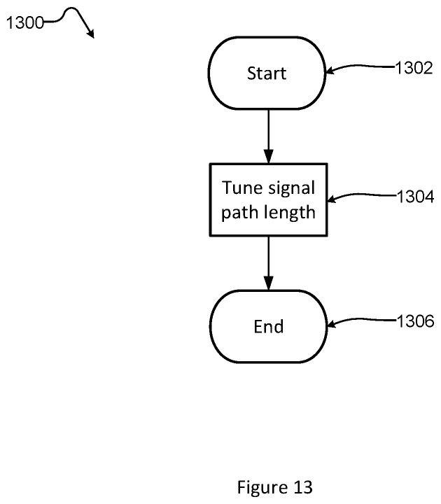

FIG. 13 is a flow diagram of an example implementation of a method of operation 1300 to reduce a gain-limiting pump self-phase-modulation of a TWPA.

Method 1300 includes acts 1302 to 1306, though those of skill in the art will appreciate that in alternative embodiments certain acts may be omitted and/or additional acts may be added.

Method 1300 starts at 1302, for example in response to a control command. At 1304, a signal path length of a resonant structure of the TWPA is electrically tuned. Electrically tuning the signal path length of the resonant structure of the TWPA may include causing at least one of a change in an effective critical current, a change in an effective inductance, or a change to a non-linear operating region of at least one of a tunable device or a segment of the TWPA. Electrically tuning the signal path length of the resonant structure of the TWPA may include applying at least one of a flux bias or a current bias to at least one of a tunable device or a segment of the TWPA.

At 1306, method 1300 ends.

Method 1300 can, in some implementations, be performed by a hybrid computing system such as hybrid computing system 1200 of FIG. 12. In some implementations, method 1300 may be performed by digital processor 1202 sending signals to quantum processor 1204, such as through controller 1218. Control commands may be provided by digital processor 1202 to cause tuning of a resonant structure of a TWPA, for example as part of control or readout systems of quantum processor 1204.

The above description of illustrated implementations, including what is described in the Abstract, is not intended to be exhaustive or to limit the implementations to the precise forms disclosed. Although specific implementations of and examples are described herein for illustrative purposes, various equivalent modifications may be made without departing from the spirit and scope of the disclosure, as will be recognized by those skilled in the relevant art. The teachings provided herein of the various implementations may be applied to other practical applications of parametric amplifiers, and other methods of quantum computation, not necessarily the exemplary methods for quantum computation generally described above.

The various implementations described above may be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to International PCT Patent Application Publication No. WO2021195368A1, SYSTEMS AND METHODS FOR SCALABLE QUANTUM COMPUTING, filed Mar. 25, 2021; and U.S. Provisional Patent Application No. 63/265,131.

These and other changes may be made to the implementations in light of the above-detailed description. In general, in the following claims, the terms used should not be construed to limit the claims to the specific implementations disclosed in the specification and the claims but should be construed to include all possible implementations along with the full scope of equivalents to which such claims are entitled. Accordingly, the claims are not limited by the disclosure.

1. A tunable traveling wave parametric amplifier (TWPA) comprising a first T-stage, the first T-stage comprising:
a first DC-SQUID;
a first interface inductively communicatively coupled to the first DC-SQUID, the first interface operable to apply a first bias to the first DC-SQUID;
a second DC-SQUID electrically communicatively coupled to the first DC-SQUID in series via a first center node;
a second interface inductively communicatively coupled to the second DC-SQUID, the second interface operable to apply a second bias to the second DC-SQUID;
a first resonator communicatively coupled to the first center node via a first coupling capacitance, the first resonator shunted to a ground, the first resonator comprising:
a first resonator capacitance;
a first resonator inductance; and
a third DC-SQUID; and
a third interface inductively communicatively coupled to the third DC-SQUID, the third interface operable to apply a third bias to the third DC-SQUID, wherein the first bias and the second bias are adjustable to reduce a ripple in a gain versus frequency response of the tunable TWPA, and the third bias is adjustable to tune a position and a width of a stop-band around a pump tone frequency of the tunable TWPA.

2. The tunable TWPA of claim 1, wherein the first interface is communicatively coupled to a first bias line, the second interface is communicatively coupled to a second bias line, and the third interface is communicatively coupled to a third bias line.

3. The tunable TWPA of claim 2, wherein the first bias line and the second bias line are communicatively coupled to a first common bias line.

4. The tunable TWPA of claim 1, further comprising a second T-stage, the second T-stage comprising:
a fourth DC-SQUID;
a fourth interface inductively communicatively coupled to the fourth DC-SQUID, the fourth interface operable to apply a fourth bias to the fourth DC-SQUID;
a fifth DC-SQUID electrically communicatively coupled to the fourth DC-SQUID in series via a second center node;
a fifth interface inductively communicatively coupled to the fifth DC-SQUID, the fifth interface operable to apply a fifth bias to the fifth DC-SQUID;
a second resonator communicatively coupled to the second center node via a second coupling capacitance, the second resonator shunted to the ground, the second resonator comprising:
a second resonator capacitance;
a second resonator inductance; and
a sixth DC-SQUID; and
a sixth interface inductively communicatively coupled to the sixth DC-SQUID, the sixth interface operable to apply a sixth bias to the sixth DC-SQUID, wherein the fourth bias and the fifth bias are adjustable to reduce the ripple in the gain versus frequency response of the tunable TWPA, and the sixth bias is adjustable to tune the position and the width of the stop-band around the pump tone frequency of the tunable TWPA.

5. The tunable TWPA of claim 4, wherein the first interface is communicatively coupled to a first bias line, the second interface is communicatively coupled to a second bias line, and the third interface is communicatively coupled to a third bias line, the fourth interface is communicatively coupled to a fourth bias line, the fifth interface is communicatively coupled to a fifth bias line, and the sixth interface is communicatively coupled to a sixth bias line.

6. (canceled)

7. (canceled)

8. A quantum processor comprising a tunable traveling wave parametric amplifier (TWPA) comprising a first T-stage, the first T-stage comprising:
a first DC-SQUID;
a first interface inductively communicatively coupled to the first DC-SQUID, the first interface operable to apply a first bias to the first DC-SQUID;
a second DC-SQUID electrically communicatively coupled to the first DC-SQUID in series via a first center node;
a second interface inductively communicatively coupled to the second DC-SQUID, the second interface operable to apply a second bias to the second DC-SQUID;
a first resonator communicatively coupled to the first center node via a first coupling capacitance, the first resonator shunted to a ground, the first resonator comprising:
a first resonator capacitance;
a first resonator inductance; and
a third DC-SQUID; and
a third interface inductively communicatively coupled to the third DC-SQUID, the third interface operable to apply a third bias to the third DC-SQUID, wherein the first bias and the second bias are adjustable to reduce a ripple in a gain versus frequency response of the tunable TWPA, and the third bias is adjustable to tune a position and a width of a stop-band around a pump tone frequency of the tunable TWPA.

9.-25. (canceled)

26. A method of increasing a bandwidth of a parametric amplifier, the method comprising:
adjusting a pump tone of the parametric amplifier;
reducing a ripple in a gain versus frequency response; and
reducing a stop-band width.

27. The method of claim 26, the parametric amplifier comprising a tunable TWPA, the tunable TWPA comprising a series array of tunable devices, wherein the reducing a ripple in a gain versus frequency response includes applying at least one of a flux bias or a current bias to at least one of the tunable devices of the series array of tunable devices.

28. The method of claim 27, wherein the applying at least one of a flux bias and a current bias to the at least one of the tunable devices includes applying a flux bias to a DC-SQUID.

29. The method of claim 26, the parametric amplifier comprising a tunable TWPA, the tunable TWPA comprising a shunting resonator, the shunting resonator comprising a DC-SQUID, wherein the reducing a stop-band width includes applying a flux bias to the DC-SQUID.

30. The tunable TWPA of claim 5, wherein the first bias line, the second bias line, the fourth bias line, and the fifth bias line are communicatively coupled to a first common bias line.

31. The tunable TWPA of claim 30, wherein the third bias line and the sixth bias line are communicatively coupled to a second common bias line.

32. The tunable TWPA of claim 5, wherein the third bias line and the sixth bias line are communicatively coupled to a first common bias line.

33. The quantum processor of claim 8, wherein the first interface is communicatively coupled to a first bias line, the second interface is communicatively coupled to a second bias line, and the third interface is communicatively coupled to a third bias line.

34. The quantum processor of claim 33, wherein the first bias line and the second bias line are communicatively coupled to a first common bias line.

35. The quantum processor of claim 8, further comprising a second T-stage, the second T-stage comprising:
a fourth DC-SQUID;
a fourth interface inductively communicatively coupled to the fourth DC-SQUID, the fourth interface operable to apply a fourth bias to the fourth DC-SQUID;
a fifth DC-SQUID electrically communicatively coupled to the fourth DC-SQUID in series via a second center node;
a fifth interface inductively communicatively coupled to the fifth DC-SQUID, the fifth interface operable to apply a fifth bias to the fifth DC-SQUID;
a second resonator communicatively coupled to the second center node via a second coupling capacitance, the second resonator shunted to the ground, the second resonator comprising:
a second resonator capacitance;
a second resonator inductance; and
a sixth DC-SQUID; and
a sixth interface inductively communicatively coupled to the sixth DC-SQUID, the sixth interface operable to apply a sixth bias to the sixth DC-SQUID, wherein the fourth bias and the fifth bias are adjustable to reduce the ripple in the gain versus frequency response of the tunable TWPA, and the sixth bias is adjustable to tune the position and the width of the stop-band around the pump tone frequency of the tunable TWPA.

36. The quantum processor of claim 35, wherein the first interface is communicatively coupled to a first bias line, the second interface is communicatively coupled to a second bias line, and the third interface is communicatively coupled to a third bias line, the fourth interface is communicatively coupled to a fourth bias line, the fifth interface is communicatively coupled to a fifth bias line, and the sixth interface is communicatively coupled to a sixth bias line.

37. The quantum processor of claim 36, wherein the first bias line, the second bias line, the fourth bias line, and the fifth bias line are communicatively coupled to a first common bias line.

38. The quantum processor of claim 37, wherein the third bias line and the sixth bias line are communicatively coupled to a second common bias line.

39. The quantum processor of claim 36, wherein the third bias line and the sixth bias line are communicatively coupled to a first common bias line.

40. The method of claim 26, wherein adjusting a pump tone of the parametric amplifier comprises adjusting a pump tone of the parametric amplifier by a controller.
